(19) United States
(12) Patent Application Publication
(10) Pub. No.: US 2015/0187883 A1
(43) Pub. Date: Jul. 2, 2015

(54) SEMICONDUCTOR DEVICE AND METHOD OF MANUFACTURING THE SAME

(71) Applicant: Hyundai Motor Company, Seoul (KR)

(72) Inventors: Jong Seok Lee, Suwon (KR); Dae Hwan Chun, Gwangmyeong (KR); Kyoung-Kook Hong, Hwaseong (KR); Junghee Park, Suwon (KR); Youngkyun Jung, Seoul (KR)

(21) Appl. No.: 14/468,819

(22) Filed: Aug. 26, 2014

(30) Foreign Application Priority Data
Dec. 27, 2013 (KR) 10-2013-0165485

(51) Int. Cl. H01L 29/16; H01L 29/423; H01L 29/36; H01L 29/51; H01L 29/78; H01L 29/66

(52) U.S. Cl. CPC H01L 29/1608; H01L 29/7827; H01L 29/66068; H01L 29/36; H01L 29/512; H01L 29/4236; H01L 29/51; H01L 29/66666

(57) ABSTRACT

A semiconductor device includes: a first n− type epitaxial layer disposed on a first surface of an n+ type silicon carbide substrate; a p type epitaxial layer disposed on the first n− type epitaxial layer; a second n− type epitaxial layer disposed on the p type epitaxial layer; an n+ region disposed on the second n− type epitaxial layer; a trench passing through the second n− type epitaxial layer, the p type epitaxial layer, and the n+ region, and disposed on the first n− type epitaxial layer; a p+ region disposed on the p type epitaxial layer and separated from the trench; and a gate insulating layer positioned in the trench, in which channels are disposed in the second n− type epitaxial layer of both sides of the trench and the p type epitaxial layer of both sides of the trench.

### CROSS-REFERENCE TO RELATED APPLICATION

This application claims under 35 U.S.C. §119(a) priority to and the benefit of Korean Patent Application No. 10-2013-0165485 filed in the Korean Intellectual Property Office on Dec. 27, 2013, the entire contents of which are incorporated herein by reference.

### BACKGROUND

(a) Field of the Invention

The present invention relates to a semiconductor device including silicon carbide (SiC), and a method of manufacturing the same.

(b) Description of the Related Art

In the field of semiconductor manufacturing, according to enlargement and high capacity of applications, there is a need for a power semiconductor device having a high breakdown voltage, a high current, and a high-speed switching characteristic.

In such a power semiconductor device, a low on resistance or a low saturated voltage is required in order to lower power loss in a conduction state when a large current flows. Further, a characteristic compatible with a backward high voltage of a PN junction which is applied to both ends of the power semiconductor device in an off state or at the moment when the switch is turned off, that is, a high breakdown voltage characteristic is required.

A metal oxide semiconductor field effect transistor (MOSFET), among power semiconductor devices, is most commonly used as a field effect transistor in a digital circuit and an analog circuit.

In a MOSFET using silicon carbide (SiC), an interface state between a silicon oxide layer serving as a gate insulating layer and silicon carbide is not sufficient to influence a flow of electrons and a current passing through a channel generated at a lower end of the silicon oxide layer, and as a result, mobility of the electrons is very low. Particularly, since an etching process is required when a trench gate is formed, low electron mobility is shown.

Further, deterioration of the electron mobility may be minimized, but a thickness of the silicon oxide layer serving as the gate insulating layer is increased due to a low threshold voltage. Since the silicon oxide layer is difficult to grow in silicon carbide, a level of difficulty in the process is increased.

The above information disclosed in this Background section is only for enhancement of understanding of the background of the invention and therefore it may contain information that does not form the prior art that is already known in this country to a person of ordinary skill in the art.

### SUMMARY

The present invention is directed to a semiconductor device and a method of manufacturing the same having advantages of reducing on resistance in a silicon carbide MOSFET to which a trench gate is applied and improving yield of the semiconductor device.

An exemplary embodiment of the present invention provides a semiconductor device, including: a first n− type epitaxial layer disposed on a first surface of an n+ type silicon carbide substrate; a p type epitaxial layer disposed on the first n− type epitaxial layer; a second n− type epitaxial layer disposed on the p type epitaxial layer; an n+ region disposed on the second n− type epitaxial layer; a trench passing through the second n− type epitaxial layer, the p type epitaxial layer, and the n+ region, and disposed on the first n− type epitaxial layer; a p+ region disposed on the p type epitaxial layer and separated from the trench; a gate insulating layer positioned in the trench; a gate electrode positioned on the gate insulating layer; an oxide layer positioned on the gate electrode; a source electrode positioned on the n+ region, the oxide layer, and the p+region; and a drain electrode positioned on a second surface of the n+ type silicon carbide substrate, in which channels are disposed in the second n− type epitaxial layer of both sides of the trench, and in the p type epitaxial layer of both sides of the trench.

The channels may include a first channel disposed in the p type epitaxial layer of both sides of the trench, and a second channel disposed in the second n− type epitaxial layer of both sides of the trench.

The first channel may be an inversion layer channel, and the second channel may be an accumulation layer channel.

An upper surface of the p+ region may be positioned on an extended line of an upper surface of the n+ region.

A thickness of the p+ region may be the same as the sum of thicknesses of the second n− type epitaxial layer and the n+ region.

The second n− type epitaxial layer and the n+ region may be disposed between the trench and the p+ region.

A doping concentration of the first n− type epitaxial layer may be the same as or different from a doping concentration of the second n− type epitaxial layer.

Another exemplary embodiment of the present invention provides a manufacturing method of a semiconductor device, including: forming a first n− type epitaxial layer on a first surface of an n+ type silicon carbide substrate; forming a p type epitaxial layer on the first n− type epitaxial layer; forming a preliminary second n− type epitaxial layer on the p type epitaxial layer; forming a p+ region by injecting p+ ions into both edges of the preliminary second n− type epitaxial layer; forming an n+ region and a second n− type epitaxial layer between the n+ region and the p type epitaxial layer by injecting n+ ions into the preliminary second n− type epitaxial layer; forming a trench at the n+ region, the second n− type epitaxial layer, the p type epitaxial layer, and the first n− type epitaxial layer; forming a gate insulating layer in the trench; forming a gate electrode on the gate insulating layer; forming an oxide layer on the gate electrode; forming a drain electrode on a second surface of the n+ type silicon carbide substrate; and forming a source electrode on the p+ region, the n+ region, and the oxide layer, in which the trench passes through the n+ region, the second n− type epitaxial layer, and the p type epitaxial layer, and channels are disposed in the second n− type epitaxial layer of both sides of the trench, and in the p type epitaxial layer of both sides of the trench.

An upper surface of the p+ region may be positioned on an extended line of the preliminary second n− type epitaxial layer.

A doping concentration of the first n− type epitaxial layer may be the same as or different from a doping concentration of the preliminary second n− type epitaxial layer.

As such, according to the exemplary embodiment of the present invention, since the channel includes both an accumulation layer channel and an inversion layer channel, an on resistance is reduced, and a manufacturing process is easy.

Further, since the semiconductor device is not largely influenced by an alignment error during etching for forming a trench, the yield of the semiconductor device may be improved.

### BRIEF DESCRIPTION OF THE DRAWINGS

FIG. 1 is a cross-sectional view of a semiconductor device according to an exemplary embodiment of the present invention.

FIG. 2 is a graph illustrating a result of simulating threshold voltages according to changes in channel width of a semiconductor device according to an Example and a semiconductor device according to a Comparative Example.

FIGS. 3 to 8 are diagrams sequentially illustrating a method of manufacturing a semiconductor device according to another exemplary embodiment of the present invention.

### DETAILED DESCRIPTION OF THE EMBODIMENTS

Hereinafter, exemplary embodiments of the present invention will be described in detail with reference to the accompanying drawings. As those skilled in the art would realize, the described embodiments may be modified in various different ways, all without departing from the spirit or scope of the present invention. On the contrary, exemplary embodiments introduced herein are provided to make disclosed contents thorough and complete and sufficiently transfer the spirit of the present invention to those skilled in the art.

In the drawings, the thickness of layers, films, panels, regions, etc., are exaggerated for clarity. It will be understood that when a layer is referred to as being “on” another layer or substrate, it can be directly on the other layer or substrate, or intervening them may also be present. Like reference numerals designate like elements throughout the specification.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

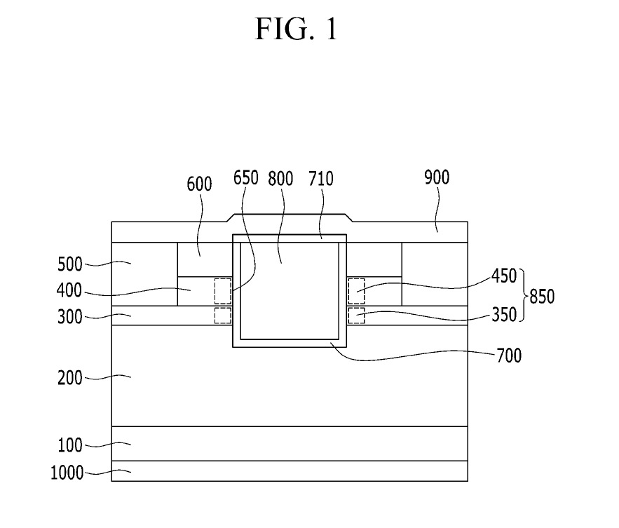

FIG. 1 is a cross-sectional view of a semiconductor device according to an exemplary embodiment of the present invention.

Referring to FIG. 1, in a semiconductor device according to the exemplary embodiment, a first n− type epitaxial layer 200, a p type epitaxial layer 300, a second n− type epitaxial layer 400, and an n+ region 600 are sequentially disposed on a first surface of an n+ type silicon carbide substrate 100. In particular, doping concentrations of the first n− type epitaxial layer 200 and the second n− type epitaxial layer 400 may be the same as or different from each other.

Further, a p+ region 500 is disposed on the p type epitaxial layer 300. The p+region 500 contacts the edges of the second n− type epitaxial layer 400 and the n+ region 600, and a thickness of the p+ region 500 is substantially the same as a sum of thicknesses of the second n− type epitaxial layer 400 and the n+ region 600. As a result, an upper surface of the p+ region 500 is positioned on an extended line of an upper surface of the n+ region 600.

A trench 650 is formed in the first n− type epitaxial layer 200, the p type epitaxial layer 300, the second n− type epitaxial layer 400, and the n+ region 600. The trench 650 passes through the p type epitaxial layer 300, the second n− type epitaxial layer 400, and the n+ region 600, and is formed in a part of the first n− type epitaxial layer 200.

The p+ region 500 is separated from the trench 650, and the p+ regions 500 are disposed at both sides of the trench 650, respectively. As a result, the second n− type epitaxial layer 400 and the n+ region 600 are disposed between the trench 650 and the p+ region 500.

A gate insulating layer 700 is formed in the trench 650, and a gate electrode 800 is formed on the gate insulating layer 700. An oxide layer 710 is formed on the gate electrode 800 and the gate insulating layer 700. The gate electrode 800 fills the trench 650, and the gate insulating layer 700 and the oxide layer 710 may be made of silicon dioxide (SiO₂).

Channels 850 of the semiconductor device are formed in the p type epitaxial layer 300 at both sides of the trench 650 and the second n− type epitaxial layer 400 at both sides of the trench 650. The channels 850 include a first channel 350 and a second channel 450. The first channel 350 is an inversion layer channel formed in the p type epitaxial layer 300 at both sides of the trench 650, and the second channel 450 is an accumulation layer channel formed in the second n− type epitaxial layer 400 at both sides of the trench 650.

As such, since the channels 850 include the first channel 350 which is the inversion layer channel and the second channel 450 which is the accumulation layer channel, the channels 850 have advantages of both the inversion layer channel and the accumulation layer channel.

The semiconductor device including only the accumulation layer channel has an advantage of preventing reduction of electron mobility to decrease on resistance, but a thickness of the gate insulating layer 700 is increased due to a low threshold voltage. Since the gate insulating layer 700 is difficult to grow in silicon carbide, as the thickness of the gate insulating layer 700 is increased, difficulty in the process is increased.

Further, in the semiconductor device including only the inversion layer channel, the thickness of the gate insulating layer 700 is smaller than the thickness of the gate insulating layer 700 of the semiconductor device including only the accumulation layer channel due to a sufficient threshold voltage. As a result, the difficulty in the process is relatively decreased. However, since an interface state between the gate insulating layer 700 made of silicon dioxide and silicon carbide is not good to influence a flow of electrons and current passing through the channel, and as a result, mobility of the electrons and the current is extremely decreased.

Since the semiconductor device according to the exemplary embodiment includes the accumulation layer channel formed by accumulating a charge carrier, an effect of the interface between the gate insulting layer 700 and silicon carbide is comparatively less, and mobility of electrons and current is improved, and as a result, on resistance is reduced. Further, since the threshold voltage is sufficient as the semiconductor device according to the exemplary embodiment includes the inversion layer channel, the thickness of the gate insulating layer 700 is not relatively large, and as a result, a manufacturing process may be simpler.

Further, the semiconductor device according to the exemplary embodiment is not largely affected by the alignment error during etching for forming the trench 650 because a change in threshold voltage according to a change of a width of the channel is low as compared with the semiconductor device including only the inversion layer channel. As a result, the yield of the semiconductor device may be improved.

A source electrode 900 is formed on the p+ region 500, the n+ region 600, and the oxide layer 710. A drain electrode 1000 is formed on a second surface of the n+ type silicon carbide substrate 100.

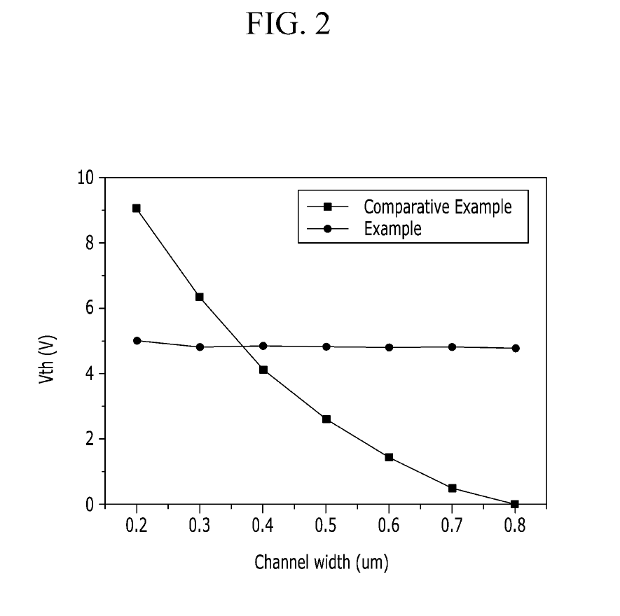

A comparison of characteristics of a semiconductor device according to an Example and a semiconductor device according to a Comparative Example will be described with reference to FIG. 2.

The semiconductor device according to the Comparative Example in FIG. 2 is a semiconductor device including only the inversion layer channel.

FIG. 2 is a graph illustrating a result of simulating threshold voltages according to changes in channel width of a semiconductor device according to the Example and a semiconductor device according to the Comparative Example.

Referring to FIG. 2, in the semiconductor device according to the Comparative Example, as the width of the channel is increased, the threshold voltage is decreased, but in the semiconductor device according to the Example, even though the width of the channel is increased, a change in threshold voltage is not large. As a result, in the semiconductor device according to the exemplary embodiment of the present invention, even though the width of the channel is changed due to the alignment error generated during trench etching, the change in threshold voltage is not large, and as a result, the process is simple. Accordingly, when the semiconductor device according to the exemplary embodiment is manufactured, since the semiconductor device is not largely influenced by the alignment error, the yield of the semiconductor device may be improved.

A manufacturing method of a semiconductor device according to another exemplary embodiment of the present invention will be described in detail with reference to FIGS. 3 to 8, and FIG. 1.

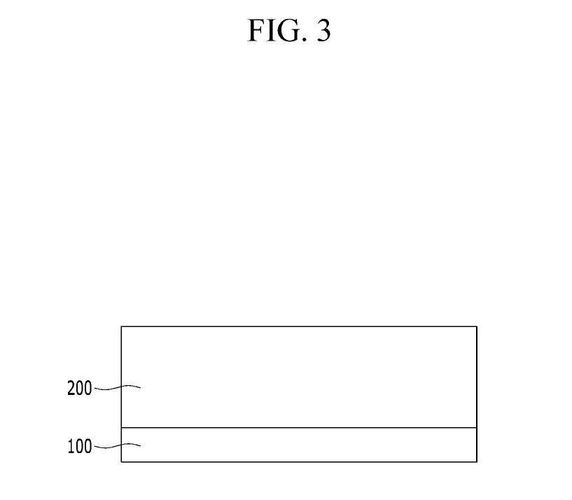

FIGS. 3 to 8 are diagrams illustrating a method of manufacturing a semiconductor device according to another exemplary embodiment of the present invention in sequence.

Referring to FIG. 3, the n+ type silicon carbide substrate 100 is prepared, and the first n− type epitaxial layer 200 is formed on the first surface of the n+ type silicon carbide substrate 100 through a first epitaxial growth.

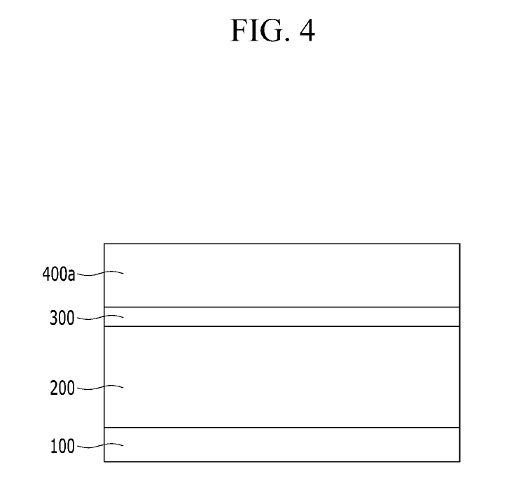

Referring to FIG. 4, after the p type epitaxial layer 300 is formed on the first n− type epitaxial layer 200 through a second epitaxial growth, the preliminary second n− type epitaxial layer 400a is formed on the p type epitaxial layer 300 through a third epitaxial growth. In particular, the doping concentrations of the first n− type epitaxial layer 200 and the second n− type epitaxial layer 400 may be the same as or different from each other. Further, the p type epitaxial layer 300 is not formed through the second epitaxial growth, but may be formed by injecting p ions on the first n− type epitaxial layer 200.

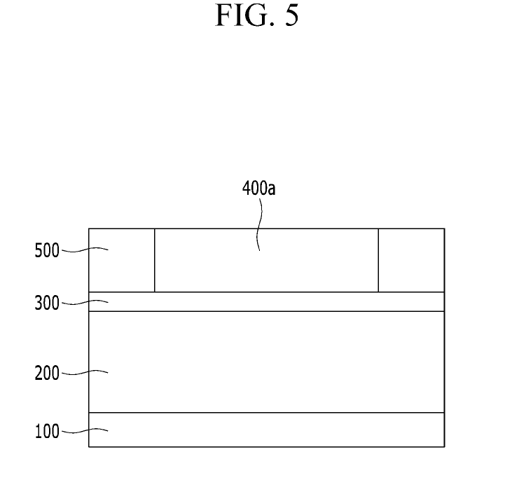

Referring to FIG. 5, the p+ region 500 is formed by injecting p+ ions into both edges of the preliminary second n− type epitaxial layer 400a. The p+ ions are injected up to a boundary of the preliminary second n− type epitaxial layer 400a and the p type epitaxial layer 300, and the p+ region 500 is formed on the p type epitaxial layer 300, and the upper surface of the p+ region 500 is positioned on an extended line of the upper surface of the preliminary second n− type epitaxial layer 400a. Preferably, the injection of the p+ ions uses a mask (not illustrated). In particular, only both edges of the preliminary second n− type epitaxial layer 400a are exposed by using the mask, and the p+ ions are injected into the exposed both edges of the preliminary second n− type epitaxial layer 400a. As such, since the p+ region 500 is formed by injecting the p+ ions, the trench for the p+ region 500 needs not to be formed.

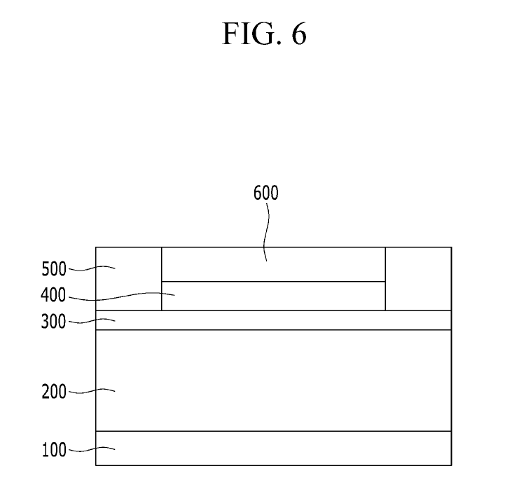

Referring to FIG. 6, the n+ region 600 is formed by injecting n+ ions into the preliminary second n− type epitaxial layer 400a. The n+ ions are not injected up to a boundary of the preliminary second n− type epitaxial layer 400a and the p type epitaxial layer 300. As a result, the n+ region 600 is separated from the p type epitaxial layer 300, and the second n− type epitaxial layer 400 is formed between the n+ region 600 and the p type epitaxial layer 300. The edge of the n+ region 600 contacts the p+ region 500. The upper surface of the n+ region 600 is positioned on an extended line of the upper surface of the p+ region 500. A thickness of the p+ region 500 is substantially the same as the sum of thicknesses of the n+ region 600 and the second n− type epitaxial layer 400. Preferably, the injection of the n+ ions uses a mask (not illustrated). In particular, the p+ region 500 is covered and the preliminary second n− type epitaxial layer 400a is exposed by using the mask, and thus the n+ ions are injected into the exposed preliminary second n− type epitaxial layer 400a.

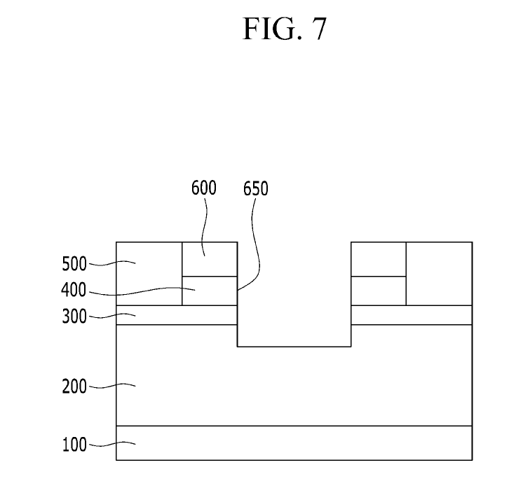

Referring to FIG. 7, the trench 650 is formed by etching the first n− type epitaxial layer 200, the p type epitaxial layer 300, the second n− type epitaxial layer 400, and the n+ region 600. The trench 650 passes through the p type epitaxial layer 300, the second n− type epitaxial layer 400, and the n+ region 600, and is formed in a part of the first n− type epitaxial layer 200.

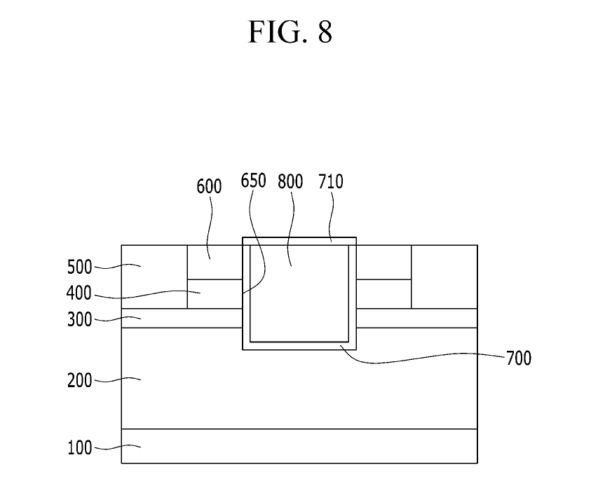

Referring to FIG. 8, the gate insulating layer 700 is formed inside the trench 650 by using silicon dioxide (SiO₂), the gate electrode 800 is formed on the gate insulating layer 700, and then the oxide layer 710 is formed on the gate electrode 800 and the gate insulating layer 700 by using silicon dioxide (SiO₂). The gate electrode 800 is formed to fill the trench 650.

Referring to FIG. 1, the source electrode 900 is formed on the p+ region 500, the oxide layer 710, and the n+ region 600, and the drain electrode 1000 is formed on the second surface of the n+ type silicon carbide substrate 100.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device, comprising:
a first n− type epitaxial layer disposed on a first surface of an n+ type silicon carbide substrate;
a p type epitaxial layer disposed on the first n− type epitaxial layer;
a second n− type epitaxial layer disposed on the p type epitaxial layer;
an n+ region disposed on the second n− type epitaxial layer;
a trench passing through the second n− type epitaxial layer, the p type epitaxial layer, and the n+ region, and disposed on the first n− type epitaxial layer;
a p+ region disposed on the p type epitaxial layer and separated from the trench;
a gate insulating layer positioned in the trench;
a gate electrode positioned on the gate insulating layer;
an oxide layer positioned on the gate electrode;
a source electrode positioned on the n+ region, the oxide layer, and the p+region; and
a drain electrode positioned on a second surface of the n+ type silicon carbide substrate,
wherein channels are disposed in the second n− type epitaxial layer of both sides of the trench, and in the p type epitaxial layer of both sides of the trench.

2. The semiconductor device of claim 1, wherein the channels include a first channel disposed in the p type epitaxial layer of both sides of the trench, and a second channel disposed in the second n− type epitaxial layer of both sides of the trench.

3. The semiconductor device of claim 2, wherein the first channel is an inversion layer channel, and the second channel is an accumulation layer channel.

4. The semiconductor device of claim 1, wherein an upper surface of the p+region is positioned on an extended line of an upper surface of the n+ region.

5. The semiconductor device of claim 4, wherein a thickness of the p+ region is the same as the sum of thicknesses of the second n− type epitaxial layer and the n+ region.

6. The semiconductor device of claim 5, wherein the second n− type epitaxial layer and the n+ region are disposed between the trench and the p+ region.

7. The semiconductor device of claim 1, wherein a doping concentration of the first n− type epitaxial layer is the same as or different from a doping concentration of the second n− type epitaxial layer.

8. A method of manufacturing a semiconductor device, comprising:
forming a first n− type epitaxial layer on a first surface of an n+ type silicon carbide substrate;
forming a p type epitaxial layer on the first n− type epitaxial layer;
forming a preliminary second n− type epitaxial layer on the p type epitaxial layer;
forming a p+ region by injecting p+ ions into both edges of the preliminary second n− type epitaxial layer;
forming an n+ region and a second n− type epitaxial layer between the n+ region and the p type epitaxial layer by injecting n+ ions into the preliminary second n− type epitaxial layer;
forming a trench at the n+ region, the second n− type epitaxial layer, the p type epitaxial layer, and the first n− type epitaxial layer;
forming a gate insulating layer in the trench;
forming a gate electrode on the gate insulating layer;
forming an oxide layer on the gate electrode;
forming a drain electrode on a second surface of the n+ type silicon carbide substrate; and
forming a source electrode on the p+ region, the n+ region, and the oxide layer,
wherein the trench passes through the n+ region, the second n− type epitaxial layer, and the p type epitaxial layer, and
channels are disposed in the second n− type epitaxial layer of both sides of the trench, and in the p type epitaxial layer of both sides of the trench.

9. The method of claim 8, wherein an upper surface of the p+ region is positioned on an extended line of the preliminary second n− type epitaxial layer.

10. The method of claim 9, wherein an upper surface of the n+ region is positioned on an extended line of an upper surface of the p+ region.

11. The method of claim 10, wherein a thickness of the p+ region is the same as the sum of thicknesses of the second n− type epitaxial layer and the n+ region.

12. The method of claim 8, wherein the channels include a first channel disposed in the p type epitaxial layer of both sides of the trench, and a second channel disposed in the second n− type epitaxial layer of both sides of the trench.

13. The method of claim 12, wherein the first channel is an inversion layer channel, and the second channel is an accumulation layer channel.

14. The method of claim 13, wherein the second n− type epitaxial layer and the n+ region are disposed between the trench and the p+ region.

15. The method of claim 8, wherein a doping concentration of the first n− type epitaxial layer is the same as or different from a doping concentration of the preliminary second n− type epitaxial layer.
